(19) United States
(12) Patent Application Publication
(10) Pub. No.: US 2012/0262896 A1
(43) Pub. Date: Oct. 18, 2012

(54) MOUNTING APPARATUS FOR EXPANSION CARD

(75) Inventor: LEI LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/095,945

(22) Filed: Apr. 28, 2011

(30) Foreign Application Priority Data
Apr. 14, 2011 (CN) 201110093646.5

(51) Int. Cl. H05K 7/00; H05K 1/14

(52) U.S. Cl. 361/784; 361/748

(57) ABSTRACT

A mounting apparatus for mounting an expansion card includes a bracket, and a mounting member mounted to the bracket. The mounting member includes a base mounted to the bracket, and a clamping member extending from a first side of a top of the base to clamp a rear end of the expansion card.

### BACKGROUND

1. Technical Field

The present disclosure relates to device mounting, and particularly, to a mounting apparatus for an expansion card.

2. Description of Related Art

Typically, a bracket is fixed in an electronic device, to secure a front end of an expansion card, and prevent the expansion card from loosening. However, the bracket cannot secure a rear end of the expansion card, when a long expansion card, such as a redundant array of independent disk (RAID) card is mounted to the bracket, the long expansion card easily loosens.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partially exploded, isometric view of an exemplary embodiment of a mounting apparatus and an expansion card, the mounting apparatus includes a mounting member.

FIGS. 2 and 3 are isometric views of the mounting member of FIG. 1, but viewed from different perspectives.

FIG. 4 is an assembled, isometric view of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

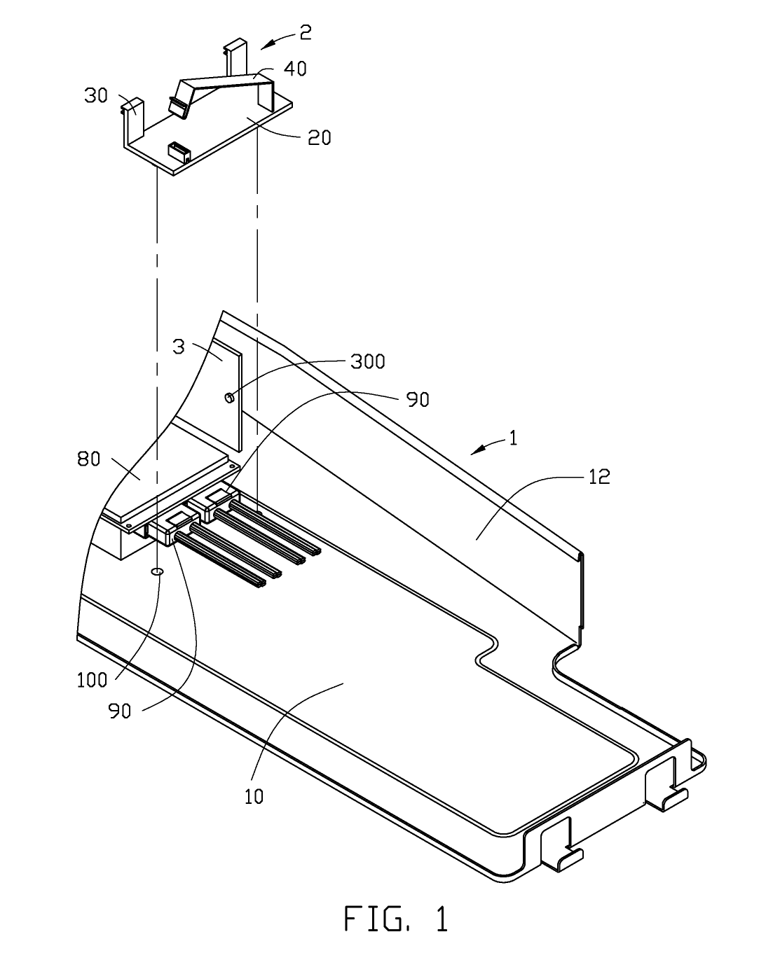

Referring to FIG. 1, an exemplary embodiment of a mounting apparatus is provided to mount an expansion card 80. The mounting apparatus includes a bracket 1, and a mounting member 2 mounted in the bracket 1.

The bracket 1 is mounted in an enclosure of an electronic device (not shown), and includes a substantially rectangular bottom plate 10, and a lateral plate 12 perpendicularly extending up from one side of the bottom plate 10. The bottom plate 10 defines two fastening holes 100.

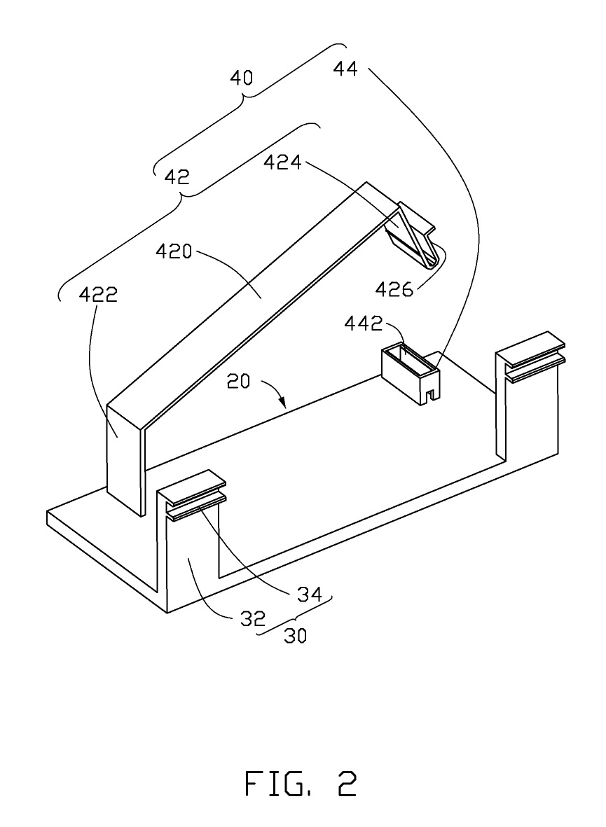

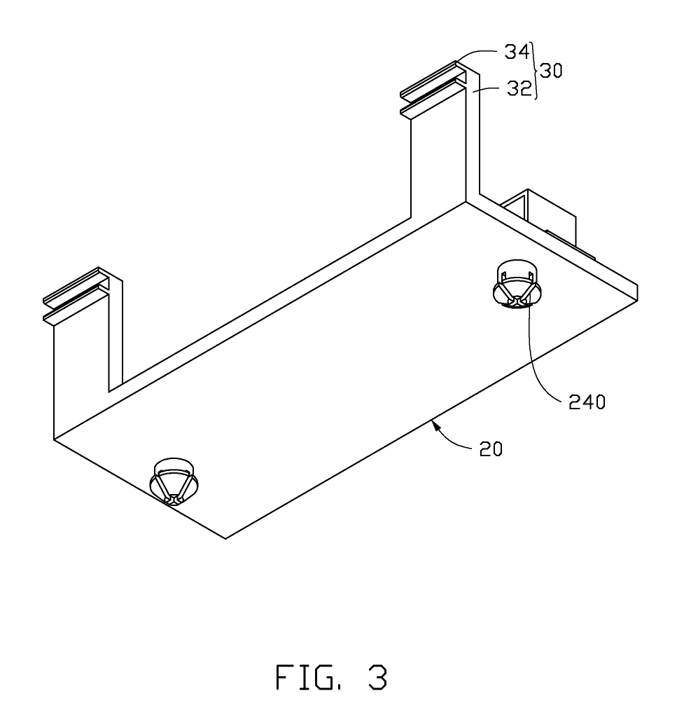

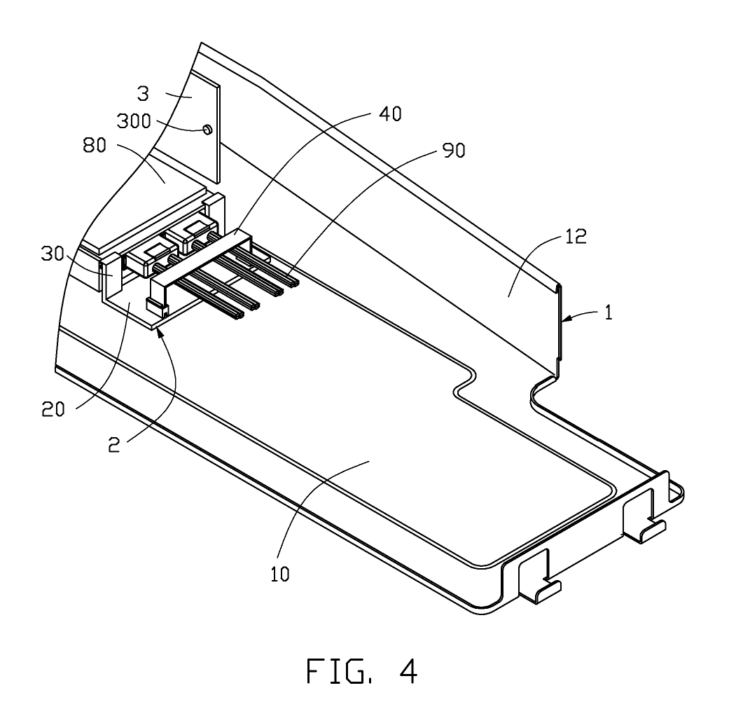

Referring to FIGS. 2 to 4, the mounting member 2 includes a substantially rectangular base 20, two clamping member 30 spaced extending up from a first side of the base 20, and a cable management member 40 extending up from a second side of the base 20 opposite to the first side. Two substantially tapered mounting blocks 240 extend down from a bottom of the base 20. Each clamping member 30 includes a connection piece 32 perpendicularly extending up from the first side of the base 20, and a substantially U-shaped clamping portion 34 extending from a distal end of the connection piece 32, away from the second side of the base 20. The cable management member 40 includes a substantially U-shaped elastic limiting portion 42, and a latching portion 44 to engage with the limiting portion 42. The limiting portion 42 includes a limiting piece 420, a mounting piece 422 substantially perpendicularly extending down from a first end of the limiting piece 420 to be mounted on the second side of the base 20, and a latching piece 424 substantially perpendicularly extending down from a second end of the limiting piece 420 opposite the first end. A distal end of the latching piece 424 opposite to the limiting piece 420 is bent up to form a substantially Z-shaped hook 426. The latching portion 44 defines a latching hole 442 to lock the hook 426.

In this embodiment, the expansion card 80 is a redundant array of independent disks (RAID) card. A side of the expansion card 80 is electrically plugged into a circuit board 3 mounted to the lateral plate 14 of the bracket 1 by screws 300. A front end of the expansion card 80 is secured by the bracket 1 as is common in the art. Opposite ends of two data cables 90 are electrically connected to a rear end of the expansion card 80 and a hard disk drive (not shown).

In use, the rear end of the expansion card 80 is clamped by the clamping portions 34 of the clamping members 30. The mounting blocks 240 of the mounting member 2 are mounted in the fastening holes 100 of the bracket 1. Thereby, the mounting member 2 is mounted on the bracket 1, so that the rear end of the expansion card 80 is mounted to the bracket 1, which can prevent the expansion card 80 from loosening. The date cables 90 extend through the cable management member 40.

It is believed that the present embodiment and its advantages will be understood from the foregoing description, and it will be apparent that various changes may be made thereto without departing from the spirit and scope of the description or sacrificing all of their material advantages, the example hereinbefore described merely being exemplary embodiment.

What is claimed is:

1. A mounting apparatus for mounting an expansion card, the mounting apparatus comprising:
a bracket;
a mounting member comprising a base mounted to the bracket, and a clamping member extending up from a first side of the base to clamp a rear end of the expansion card.

2. The mounting apparatus of claim 1, wherein the clamping member comprises a connection piece substantially perpendicularly extending up from the first side of the base, and a clamping portion extending from a distal end of the connection piece opposite to the base to clamp the rear end of the expansion card.

3. The mounting apparatus of claim 2, wherein the clamping portion is substantially U-shaped, and extends away from a second side of the base opposite to the first side.

4. The mounting apparatus of claim 2, wherein the mounting member further comprises a cable management member set on the second side of the base, to manage a plurality of data cables electrically connected to the rear end of the expansion card.

5. The mounting apparatus of claim 4, wherein the cable management member comprises a substantially U-shaped elastic limiting portion, and a latching portion set on the second side of the base to latch the limiting portion.

6. The mounting apparatus of claim 5, wherein the limiting portion comprises a limiting piece, a mounting piece extending from a first end of the limiting piece to be mounted on the second side of the base, and a latching piece extending from a second end of the limiting piece opposite the first end, a distal end of the latching piece forms a hook, the latching portion defines a latching hole to latch the hook.

7. The mounting apparatus of claim 1, wherein the bracket comprises a bottom plate, and a lateral plate substantially perpendicularly extending up from a side of the bottom plate, a circuit board is mounted to the lateral plate to be electrically connected to the expansion card.

8. The mounting apparatus of claim 1, wherein a plurality of mounting blocks protrudes from a bottom of the base of the mounting member, the bracket comprises a bottom plate, the bottom plate defines a plurality of fastening holes to lock the mounting blocks.
